(19) United States
(12) Patent Application Publication
(10) Pub. No.: US 2015/0325393 A1
(43) Pub. Date: Nov. 12, 2015

(54) MEMS Switch

(71) Applicant: Analog Devices Global, Harnilton (BM)

(72) Inventors: Bernard P. Stenson, County Limerick (IE); Darren R. Lee, Raheen (IE); Padraig L. Fitzgerald, County Cork (IE); Michael Morrissey, County Limerick (IE)

(21) Appl. No.: 14/667,022

(22) Filed: Mar. 24, 2015

Related U.S. Application Data
(60) Provisional application No. 61/990,434, filed on May 8, 2014.

(51) Int. Cl. H01H 33/64; B81C 1/00; H01H 59/00

(52) U.S. Cl. CPC H01H 33/64; H01H 59/00; B81C 1/00261

(57) ABSTRACT

A micromachined switch has a cavity with an atmosphere configured to reduce sparking between switch contacts during opening and closing operations.

### PRIORITY

This patent application claims priority from provisional U.S. patent application Ser. No. 61/990,434 filed May 8, 2014 entitled, “MEMS SWITCH,” and naming Bernard Patrick Stenson, Darren R. Lee, Padraig L. Fitzgerald, and Michael Morrissey as inventors, the disclosure of which is incorporated herein, in its entirety, by reference.

### FIELD

Various embodiments related to a MEMS switch having a cavity that mitigates sparks.

### BACKGROUND

MEMS switches are gaining popularity as reliable small size switching alternatives to relays and as alternatives to field effect transistors. However, in general, MEMS switches are only operated to change state between open when there is no current flowing through the switch, and closed when there is no voltage across the switch, or vice versa. This is to avoid arcing within the MEMS switch, which can damage the material of the switch contacts. The dimensions of MEMS switches are typically very small, with the contacts separated by very small distances (e.g., 1 micron) in the open position. Arcing undesirably could cause the profile of the switch contacts to change in such a way that 1) the switch could become permanently conducting or 2) the switch could became a permanently open circuit due to damage.

### SUMMARY

According to the illustrative embodiments, a micro machined switch has a sealed enclosure, and first and second switch contacts movable between a closed position in which the first and second switch contacts touch one another, and an open position in which the first and second switch contacts are separated from one another. The sealed enclosure illustratively contains a spark quenching gas.

Spark quenching gases may also be known as dielectric gases. Such gases can reduce the likelihood that a spark will occur when a switch is opened or closed. Among other things, the spark quenching gas may be a single gas, or it may be a mixture of gases. For example, the spark quenching gases can include fluorine bound with sulfur or a hydrocarbon.

According to a second embodiment, a method of fabricating a MEMS switch fills an enclosure having the MEMS switch contacts with a spark quenching gas.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically illustrates a first embodiment of a switch in cross section.

FIG. 2 schematically shows an embodiment in which a MEMS switch is provided within an hermetic package.

### DESCRIPTION OF ILLUSTRATIVE EMBODIMENTS

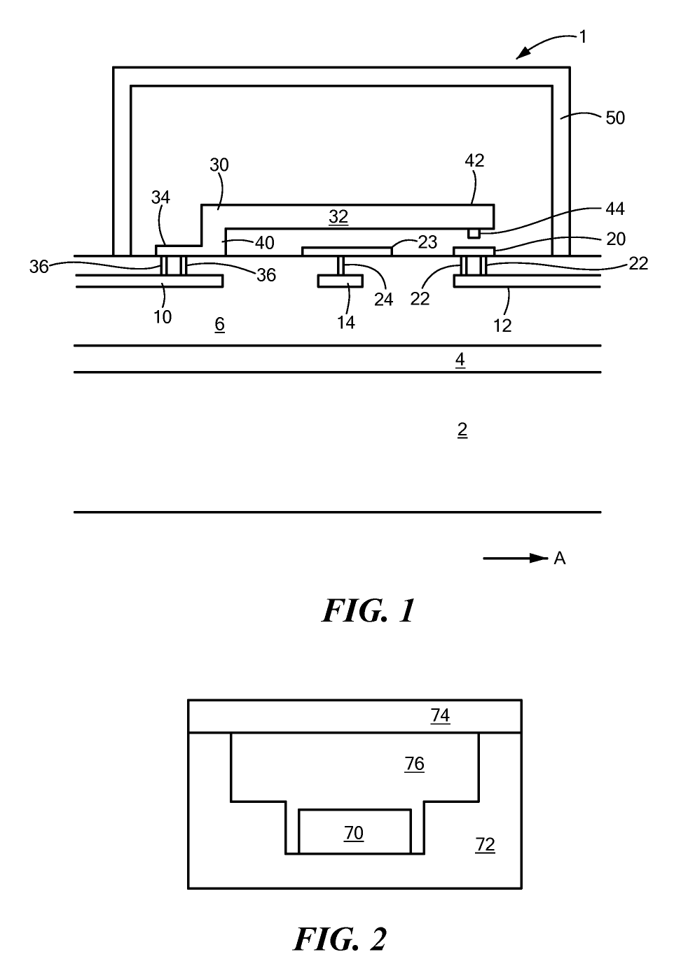

FIG. 1 schematically shows an embodiment of a MEMS (micro-electro-mechanical system) switch generally indicated 1. The switch 1 is formed over a substrate 2. The substrate 2 may be a semiconductor, such as silicon. The silicon substrate may be a wafer formed by processes such as the Czochralski process (“CZ”) or the float zone process. The CZ process is less expensive and gives rise to a silicon substrate that typically is more physically robust than that obtained using the float zone process, although float zone typically delivers silicon with a higher resistivity, which is more suitable for use in high frequency circuits.

The silicon substrate may optionally be covered by a layer 4 of undoped polysilicon. The layer 4 of polysilicon acts as a carrier lifetime killer. This enables the high frequency performance of the CZ silicon to be improved.

A dielectric layer 6, which may be of silicon oxide (generally SiO₂), is formed over the substrate 2 and the optional polysilicon layer 4. The dielectric layer 6 may be formed in two phases such that a conductive layer, such as a metal layer, may be deposited, masked and etched to form conductors 10, 12 and 14. Then, a second phase of deposition of the dielectric 6 may be performed to form the structure shown in FIG. 1, in which the conductors 10, 12 and 14 are embedded within the dielectric layer 6.

The surface of the dielectric layer 6 has a first switch contact 20 provided by a relatively hard wearing conductor formed over a portion of the layer 6. The first switch contact 20 is connected to the conductor 12 by way of one or more conductive paths, such as vias 22. Similarly a control electrode 23 may be formed above the conductor 14 and be electrically connected to it by one or more conductive paths, such as vias 24.

A support 30 for a switch member 32 is also formed over the dielectric layer 6. The support 30 comprises a foot region 34 which is deposited above a selected portion of the layer 6 such that the foot region 34 is deposited over the conductor 10. The foot region 34 is connected to the conductor 10 by way of one or more conductive paths, such as vias 36.

The conductors 10, 12 and 14 may be made of any of a number of different known conductors, such as a metal like aluminum or copper. In a similar manner, the vias may be made of aluminum, copper, tungsten or any other suitable metal or conductive material. The first switch contact 20 may be any suitable metal, such as rhodium as it is hard wearing. For ease of processing, the control electrode may be made of the same material as the first switch contact 20 or the foot region 34. The foot region 34 may be made of a metal (e.g., gold) or other conductor.

The support 30 further comprises at least one upstanding part 40, for example in the form of a wall or a plurality of towers that extends away from the surface of the dielectric layer 6.

The switch member 32 forms a moveable structure that extends from an uppermost portion of the upstanding part 40. The switch member 32 is typically (but not necessarily) provided as a cantilever which extends in a first direction, shown in FIG. 1 as direction A, from the support 30 toward the first switch contact 20. An end portion 42 of the switch member 20 extends over the first switch contact 32 and carries a depending contact 44. The upstanding part 40 and the switch member 32 may be made of the same material as the foot region 34.

Any of a variety of different packaging methods may be employed to protect the fragile microstructure of the switch 1. To that end, the MEMS structure, in this example, is protected by a cap structure 50 that is bonded to the surface of the dielectric layer 6 or other suitable structure, enclosing the switch member 32 and the first switch contact 20 (among other things). Suitable bonding techniques are known to the person skilled in the art. For example, the cap structure 50 may be bonded to the dielectric layer 6 using seal glass or a metal bond.

The switch 1 can be used to replace relays and solid state transistor switches, such as FET switches. Many practitioners in the field have adopted a terminology that is used with FETs. Thus, borrowing from the FET field, the conductor 10 may be referred to as a source, the conductor 12 may be referred to as a drain, and the conductor 23 may be referred to as a gate connected to a gate terminal 14. The source and drain may be swapped without affecting the operation of the switch.

In use, a drive voltage is applied to the gate 23 from a drive circuit. The potential difference between the gate 23 and the switch member 32 causes, for example, positive charge on the surface of the gate 23 to attract negative charge on the lower surface of the cantilevered switch member 32. This causes a force to be exerted that pulls the switch member 32 toward the substrate 2. This force causes the switch member to bend such that the depending contact 44 contacts the first switch contact 20.

In practice, the switch is over driven to hold the contact 44 relatively firmly against the first switch contact 20.

The cap structure 50 allows control of the environment around the MEMS cantilever, and more importantly, the first switch contact 20 and the depending contact 44. In illustrative embodiments, the environment may be evacuated to reduce air resistance acting on the cantilevered beam 32. However, an evacuated enclosure is not always appropriate as it may be difficult to achieve during device fabrication. Filling the cavity with air is convenient, but does not give the best spark quenching performance.

The inventors discovered that the operation of a MEMS switch may be improved by replacing the atmosphere within the cap structure 50 by a suitable gas that quenches sparks—a spark quenching gas. For example, a suitable gas is sulfur hexafluoride, SF₆, which has good discharge and arc quenching properties. Furthermore, its decomposition products tend to quickly reform SF₆. SF₆ need not be used alone and, for example, can be used in conjunction with other gases, such as nitrogen, to provide a lower cost alternative. Other gases that may be used may include 1,2-dichlorotetrafluoroethane CF₂ClCF₂Cl; dichlorofluoromethane CF₂Cl₂; trifluoromethane CF₃H; 1,1,1,3,3,3-hexafluoropropane CF₃CH₂CF₃, carbon tetrafluoride CF₄; hexafluoroethane C₂F₆; 1,1,1,2-tetrafluoroethane C₂H₂F₄; perfluoropropane C₃F₈; Octafluorocyclobutane C₄F₈; and perfluorobutane C₄F₁₀. Dichlorofluoromethane may be used in combination with nitrogen. Carbon tetrafluoride is a relatively poor insulator when used alone, but when combined with sulfur hexafluoride, it has the advantage of significantly lowering the mixture's boiling point, favorably preventing condensation at extremely low temperatures.

The possibility of condensation, which could give rise to surface tension between the switch contacts pulling the switch to a closed position, has up to now motivated those skilled in the art to avoid filling the cavity with anything other than a dry low boiling point gas, such as dried nitrogen or dried air. The use of combinations of the above gases, possibly in combination with other gases, inside a MEMS switch provided enhanced switching performance, and protection against (or the ability to perform) “hot” switching, which is the term used to describe closing the switch in the presence of a non-zero voltage across the switch, or opening the switch in the presence of a non-zero current.

Some embodiments of the invention do not use a wafer-level cap (i.e., a cap 50). Instead, rather than using a cap 50, such may use higher level packaging, such as integrated circuit packaging surrounding the substrate 2 on which the MEMS component is formed. Such a package should provide a gas impermeable environment that is filled with a suitable spark quenching gas. Such an arrangement is shown in FIG. 2, where a MEMS component (such as one or more switches) is provided (shown as “substrate 70”) within a cavity package. The substrate 70/switch is enclosed within a housing formed by first and second parts 72 and 74, which can be regarded as forming a hollow body and a lid, which cooperate to define a chamber 76 in which the substrate 70 is located. The first and second parts 72 and 74 may be made of any conventional material, such as ceramic or plastics. As known by those in the art, the switch/substrate 70 is secured to the part 72, and wire bonds connect to contacts (e.g., leads if using a lead frame package) made as known to the person skilled in the art. The chamber 76 may then be filled with a suitable spark quenching gas, and the lid 74 sealed to the body 72. Other embodiments may package the device in an environment having spark quenching gas, thus automatically sealing the gas in the body when the part 74 is coupled with part 72. Illustrative embodiments form the chamber 76 to be hermetic.

The MEMS switch may be included within an integrated circuit.

Although the claims have been presented in single dependency format, it is to be understood that any claim can depend from any preceding claim of the same type, except where that is clearly technically infeasible.

Although the above discussion discloses various exemplary embodiments of the invention, it should be apparent that those skilled in the art can make various modifications that will achieve some of the advantages of the invention without departing from the true scope of the invention.

1. A micromachined switch comprising a sealed enclosure, and first and second switch contacts movable between a closed position in which the first and second switch contacts touch one another, and an open position in which the first and second switch contacts are separated from one another, wherein the sealed enclosure contains a spark quenching gas.

2. A micromachined switch as claimed in claim 1, in which the spark quenching gas is not solely air, nitrogen or a vacuum.

3. A micromachined switch as claimed in claim 1, in which the spark quenching gas comprises sulfur hexafluoride.

4. A micromachined switch as claimed in claim 1, in which the spark quenching gas comprises nitrogen.

5. A micromachined switch as claimed in claim 1, in which the spark quenching gas comprises nitrous oxide.

6. A micromachined gas as claimed in claim 1, in which the spark quenching gas comprises dichlorotetrafluoroethane.

7. A micromachined gas as claimed in claim 1, in which the spark quenching gas comprises dichlorodifluoromethane.

8. A micromachined switch as claimed in claim 1, in which the spark quenching gas comprises hexafluoropropane.

9. A micromachined switch as claimed in claim 1, in which the spark quenching gas comprises carbon tetrafluoride.

10. A micromachined switch as claimed in claim 1, in which the spark quenching gas comprises hexafluoroethane.

11. A micromachined switch as claimed in claim 1, in which the spark quenching gas comprises tetrafluoroethane.

12. A micromachined switch as claimed in claim 1, in which the spark quenching gas comprises perfluoropropane.

13. A micromachined switch as claimed in claim 1, in which the spark quenching gas comprises octafluorocyclobutane.

14. A micromachined switch as claimed in claim 1, in which the spark quenching gas comprises perfluorobutane.

15. A micromachined switch as claimed in claim 1, in which the enclosure is a cap.

16. A micromachined switch as claimed in claim 1, in which the enclosure is an

17. The method of forming a MEMS switch as in claim 1 wherein the enclosure includes a wafer level package integrated circuit package.

18. A method of forming a MEMS switch where the switch includes switch contacts within an enclosure, the method comprising filling the enclosure with a spark quenching gas.
